(19) United States
(12) Patent Application Publication
(10) Pub. No.: US 2002/0008702 A1
(43) Pub. Date: Jan. 24, 2002

(54) INTERACTIVE SCALABLE DIGITAL OSCILLOSCOPE DISPLAY

(76) Inventor: HARRY MARK GILBERT, PORTAGE, MI (US)

Correspondence Address: PEPPER HAMILTON, 600 FOURTEENTH STREET NW, WASHINGTON, DC, 20005, US

(21) Appl. No.: 09/185,801

(22) Filed: Nov. 4, 1998

(51) Int. Cl. G09G 5/36; G01R 13/00; F02P 17/00

(52) U.S. Cl. 345/440.1; 345/856; 702/66

(57) ABSTRACT

A preferred data display apparatus (10) includes an engine analyzer (14), computer (16) and a display device (18). The computer (16) receives waveform data representative of a waveform characteristic of engine operation from the analyzer (14) and produces a waveform display on the device (18) representative of the waveform. The waveform display includes segments (30a, 30b, 30c) displayed in different colors and in a three-dimensional representation. In preferred forms, a mouse (20) is used to snap a cursor (32) along the waveform and display includes amplitude and time data representative of the position coordinates of the cursor (32) and thereby representative of the cursor's position on the waveform. The preferred apparatus is operable to display waveforms derived from different sources.

### RELATED APPLICATIONS

Not Applicable

### FEDERALLY SPONSORED RESEARCH OR DEVELOPMENT

Not Applicable

### MICROFICHE APPENDIX

Included herewith is a microfiche appendix illustrating the preferred computer program incorporated as part of the disclosure hereof including 1 sheet with a total of 43 frames.

### BACKGROUND OF THE INVENTION

1. Field of the Invention

The present invention relates to the field of engine analyzers in the display of data therefrom. In particular, the invention is concerned with a data display apparatus operable to produce a waveform display representative of a waveform having a plurality of segments.

2. Description of the Prior Art

Engine analyzers are used to display waveforms characteristic of the operation of an engine including segments representative of the firing of each cylinder. The waveforms tend to be complex and difficult to analyze visually. Moreover, it would be helpful to analyze and compare data from different sources such as the primary and secondary of the engine coil, but prior art systems are unable to accomplish this effectively. Accordingly, the prior art points out the need for improvement in the display of complex waveforms.

### SUMMARY OF THE INVENTION

The present invention satisfies the prior art needs discussed above and provides a distinct advance in the state of the art. More particularly, the data display apparatus hereof provides for a visually enhanced display of complex waveforms including waveforms derived from different sources.

The preferred data display apparatus in accordance with the present invention includes an image display device coupled with a computer. The computer stores waveform data representative of a waveform having a plurality of data segments and is operable, under program control, for producing display signals and to provide the signals to the display device for producing a waveform display with a plurality of data segments in different colors.

In preferred forms, a cursor snaps along the waveform and the display presents a numerical display of the position coordinates of the cursor. The preferred embodiment is also operable to present a plurality of waveforms derived from different sources. Other preferred aspects of the present invention are disclosed herein.

### BRIEF DESCRIPTION OF THE DRAWINGS

FIG. 1 is a schematic representing the preferred data display apparatus in accordance with the present invention shown in use with a vehicle;

FIG. 2 illustrates a waveform display presented on the display device of FIG. 1;

FIG. 3 illustrates another waveform display presented on the display device of FIG. 1;

FIG. 4 illustrates a display showing two waveforms derived from different sources as displayed on the display device of FIG. 1;

FIG. 5 illustrates a display showing the use of crosshair cursors for measuring the firing line of a cylinder;

FIG. 6 illustrates a display for comparing values among cylinders;

FIG. 7 illustrates another display for comparing values among cylinders;

FIG. 8 illustrates another display for comparing values among the cylinders;

FIG. 9 illustrates the enlargement of a waveform corresponding to a selected form; and

FIG. 10 illustrates waveforms from two different sources.

### DETAILED DESCRIPTION OF THE PREFERRED EMBODIMENT

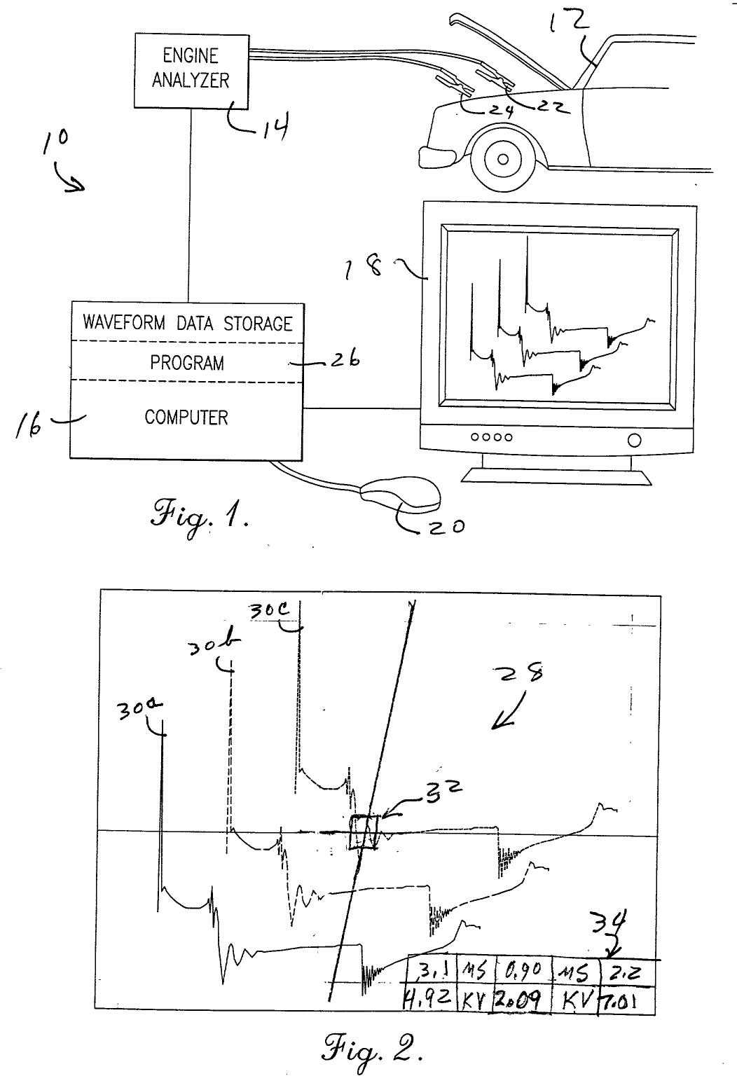

FIG. 1 illustrates preferred data display apparatus 10 in accordance with the present invention showing use with vehicle 12. Preferred apparatus 10 includes engine analyzer 14, computer 16, display device 18 and computer mouse 20.

Engine analyzer 14 is a conventional unit such as Bear Model 270 engine analyzer. In use, connectors such as clips 22, 24 are used to connect analyzer 14 to selected engine components of the vehicle 12 such as the primary or the secondary of the coil, or the fuel injectors, for example. Analyzer 14 receives signals that represent a waveform characteristic of the operation of the vehicle's engine. In particular, the waveform typically includes segments that represent the firing of the individual cylinders. Analyzer 14 converts the analog engine signals to digital signals in the form of waveform data representative of the waveform and having a plurality of data segments representative of the waveform segments.

Computer 16 is preferably a conventional personal computer having interface card operable to connect with engine analyzer 14 to receive the waveform data therefrom. Computer 16 includes waveform data storage such as random access memory (RAM) for storing the waveform data. The microfiche appendix included as part of a disclosure hereof illustrates preferred program 26 for operating computer 16 as a special purpose computer in accordance with the present invention.

Display device 18 is a conventional computer monitor. Conventional mouse 20 is connected to computer 16 for moving the cursor on display device 18.

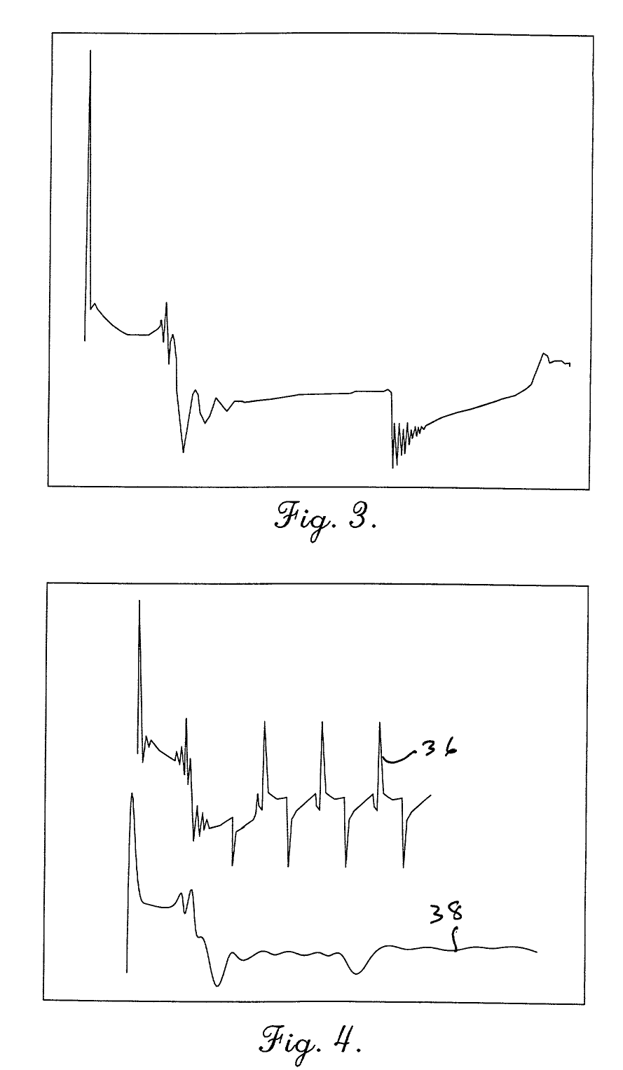

In operation, program 26 responds to the waveform data by producing a waveform display representative thereof on display device 18. FIG. 2 illustrates an example of a waveform display 28. In this display, the individual segments 30a, 30b, and 30c are separated and presented in a receding fashion representative of a three-dimensional display. If apparatus 10 is used for engine analysis, there would be a segment presented for each cylinder of the engine. For clarity of illustration, FIG. 2 illustrates only three segments.

In the preferred embodiment, boundary areas adjacent the edges of the display (within 26 pixels) are “live” in that computer 16 and program 26 respond to placement of cursor in one of these boundary areas. This response includes changing the display by moving the display up, down, left, right or diagonally.

As those skilled in the art appreciate, the number of data points in each data segment are not necessarily equal. For example, some engines present an “odd fire” in which some of the cylinders do not fire for as long as other cylinders. In such cases, the number of data points for the various segments will not be equal. Program 26 handles each segment individually regardless of the number of data points.

In the preferred embodiment, program 26 generates the display signals so that each segment 30a-c is in a different color. As those skilled in the art will appreciate, and as illustrated in FIG. 2, such data displays can be complex. However, the presentation of the individual segments in different colors enhances the ability for visual analysis of the waveform and thereby enhances a technician's troubleshooting ability by more readily comparing one segment to another.

Program 26 is also operable to generate cross-hair cursor 32 on the display. As is typical, the horizontal line of the cursor represents the y-axis line and the vertical line of the cursor represents the x-axis line. Program 26 is operable to determine the position of cursor 32 relative to the waveform and to orient the x-axis line as a tangent to the waveform at the data point on which the cursor is residing. This provides additional aid in visualizing the data itself and the performance of the engine. In the preferred embodiment, program 26 snaps cursor 32 along the waveform. That is, as the user moves the mouse 20, program 26 moves the cursor horizontally according to the mouse movements but positions the cursor vertically according to the position of the waveform. In this way, the cursor remains on the waveform and tracks the waveform. In addition, both the x-axis and the y-axis lines can be moved independently.

Display 28 also includes numerical display 34, which contains six pieces of information as shown. These include the amplitude and time position of the lefthand cursor crosshair (lefthand column), the amplitude and time position of the righthand cursor crosshair (righthand column), and the absolute difference, or “delta” of these two crosshairs (center column). The units of time (ms) and the amplitude (kV) are only for illustration in that other units may be used. With this information, the same data point on various waveform segments can be compared as a substantial enhancement to the analytical ability provided by program 26.

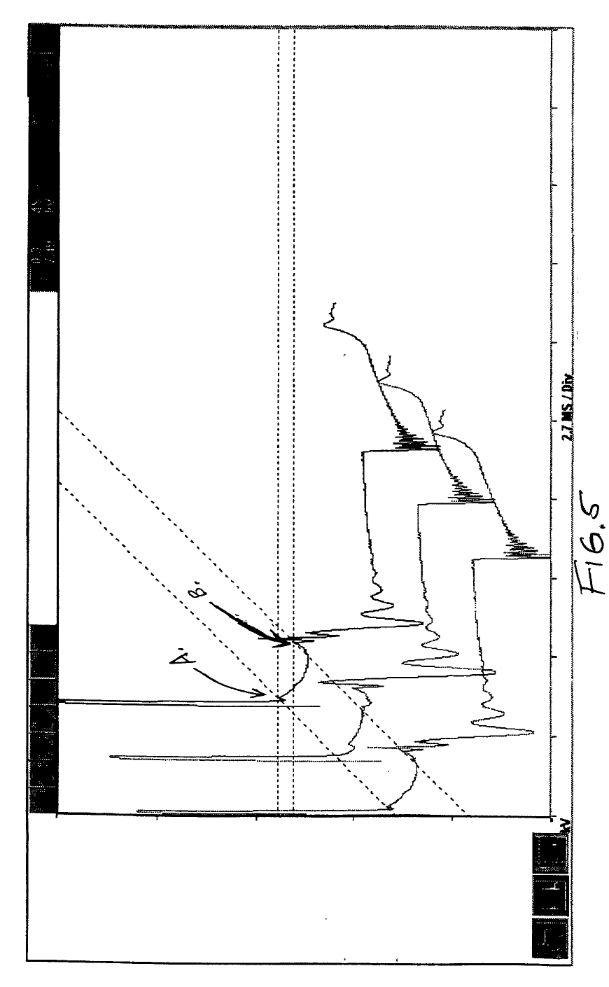

FIG. 3 illustrates the single waveform segment such as segment 30a in an enlarged format. By using mouse 20 to position cursor 32 on a selected segment, the user can click on this segment. Program 26 responds by the graying-out other segments and enlarging the selected segment. This enables enhanced visual analysis of the waveform and of a particular segment. Such is an advantage if the operation of a particular cylinder is suspected as being out of specification.

FIG. 4 illustrates waveforms 36 and 38 derived from two different sources. Computer 16 is operable to store first and second waveform data received from engine analyzer 14 and program 26 produces first and second waveforms 36, 38 representative thereof on display device 18. For example, waveform 36 could represent the firing of a particular cylinder as monitored at the primary of the coil and waveform 38 could represent the firing of that same cylinder as monitored at the secondary of the coil. Program 26 displays both waveforms thereby enhancing the ability for visual analysis.

FIGS. 5-10 illustrate other displays that can be generated. FIG. 5 shows how the crosshair cursors can be useful in measuring the ‘firing line’ of a cylinder. The left cursor (A) is placed at the beginning of the firing, the right cursor (B) is at the end of the firing. The readout above shows that the first cursor's horizontal line is 0.3 ms from the start of the wave, and the second cursor is at 2.2 ms. The delta value shown (center value) is the difference between the two cursors, or 1.90 ms. The vertical values, in kV, are similarly shown. The left cursor shows 7.49 kV, the right cursot shows 7.01 kv, with the delta showing 0.48 kv.

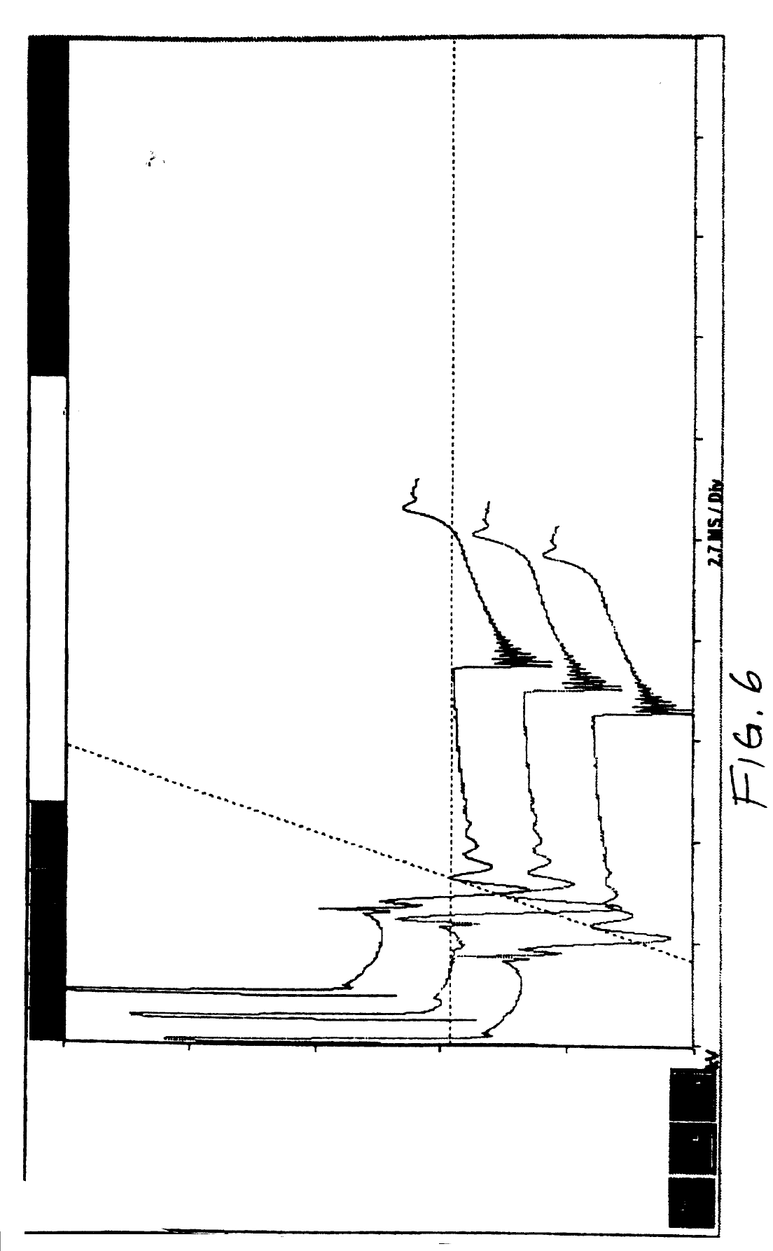

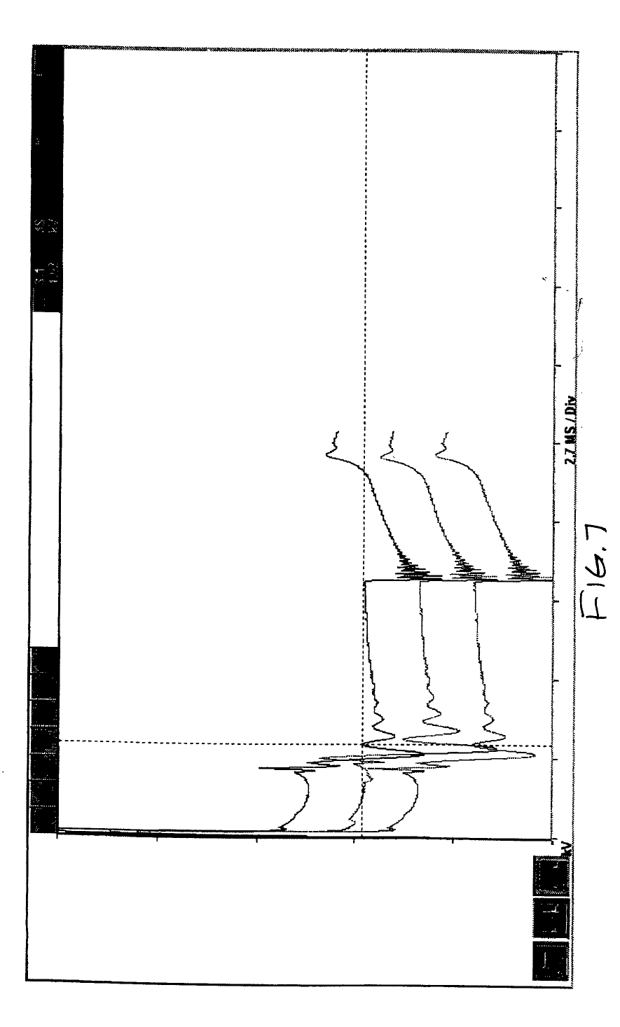

FIG. 6 illustrates how the crosshair cursor can be positioned on one cylinder (here cylinder 3) and be useful to compare with values in the other cylinders. The vertical cursor line is adjusted to always maintain the same “slant” that the 3d cylinder display has.

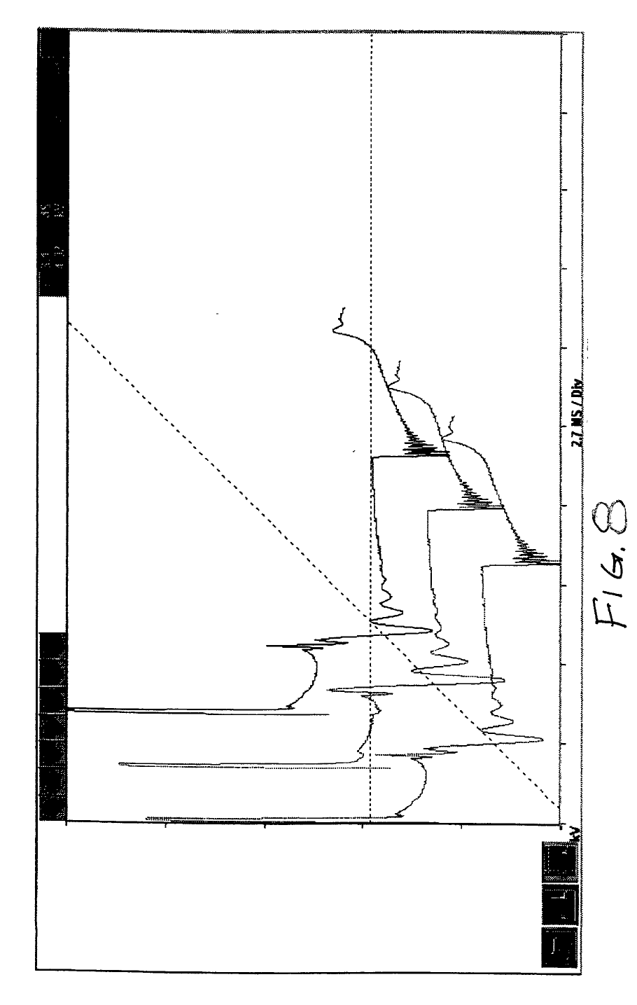

FIG. 7 illustrates how the crosshair cursor can be positioned on one cylinder (here cylinder 3) and be useful to compare with values in the other cylinders. The vertical cursor line is adjusted to always maintain the same “slant” that the 3d cylinder display has.

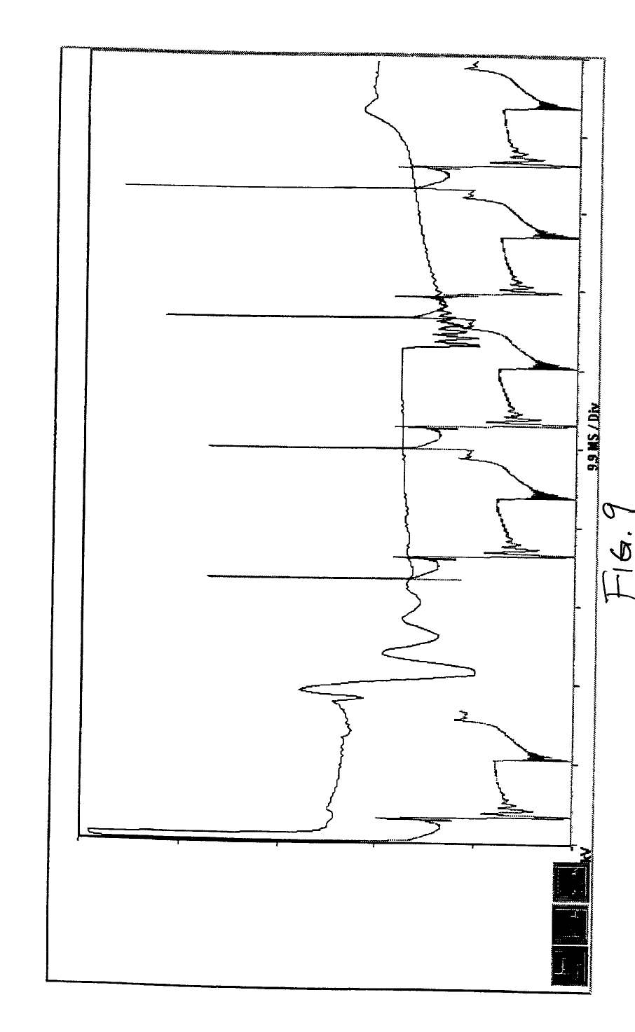

FIG. 8 illustrates how the crosshair cursor can be positioned on one cylinder (here cylinder 3) and be useful to compare with values in the other cylinders. The vertical cursor line is adjusted to always maintain the same “slant” that the 3d cylinder display has.

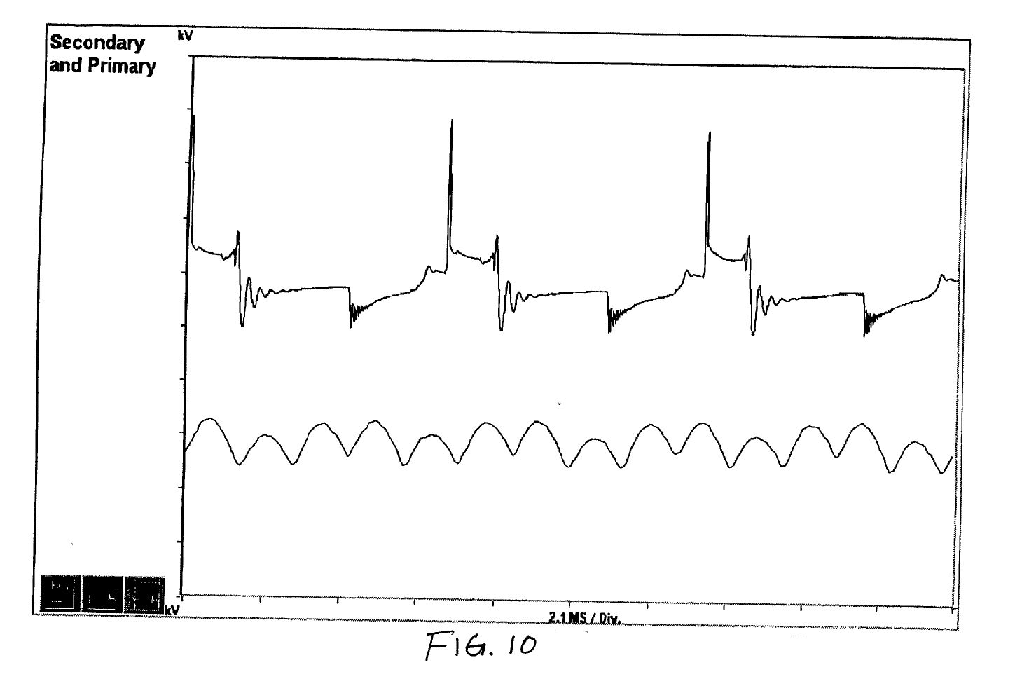

FIG. 9 is a view illustrating when a segment is selected, is enlarged to fill the display while the other segments are “grayed-out.” FIG. 10 is another illustration showing waveforms from different sources on the same display. For example, in FIG. 10 the upper waveform is a secondary waveform and the lower is a diode pattern waveform.

Those skilled in the art will appreciate that the present invention encompasses many variations in the preferred embodiment described herein. For example, the invention can be used to provide an enhanced visual display of waveforms from a wide variety of sources and not limited to engine analysis. In such cases, the preferred apparatus would not include the engine analyzer.

Having thus described the preferred embodiment, the following is claimed as new and desired to be secured by Letters Patent:

1. A data display apparatus comprising:
an image display device operable to produce a display; and
a computer coupled with said display device including
data storage means for storing waveform data representative of a waveform having a plurality of data segments, and
display signal means responsive to said waveform data for producing display signals representative thereof and for providing said display signals to said monitor for producing a waveform display thereon representative of said waveform wherein said waveform display presents a plurality of said segments in different colors.

2. The apparatus of claim 1, said waveform display presenting said segments as a three-dimensional representation.

3. The apparatus of claim 1, said computer including cursor means for generating a cursor on said waveform display, said apparatus further including a mouse coupled with said computer and operable to move said cursor and for clicking on a selected one of said segments, said display signal means including means responsive to said clicking for enlarging said selected one of said segments.

4. The apparatus of claim 1, said computer including cursor means for generating a cursor on said waveform display, said apparatus further including a mouse coupled with said computer and operable to move said cursor and for clicking on a selected one of said segments, said waveform display including position coordinates, said display signal means including means for tracking said cursor, snapping said cursor along said waveform and presenting a numerical display of the position coordinates of said cursor.

5. The apparatus of claim 4, said cursor being a cross-hair cursor including a horizontal line and a second line intersecting therewith, said display signal means including means for orienting said second line as a tangent to said waveform at the position of the cursor thereon.

6. The apparatus of claim 5, said waveform data being first waveform data, said waveform being a first waveform, said waveform display being a first waveform display, said data storage means including means for storing second waveform data representative of a second waveform for producing display signals in order to produce second waveform display representative thereof on said image display device, said second waveform data being derived from a different source than said first waveform data.

7. The apparatus of claim 6, further including an engine analyzer coupled with said computer and operable to couple with an engine to produce said waveform data representative of the operation of said engine and to provide said waveform data to said computer.

8. The apparatus of claim 1, said waveform data being first waveform data, said waveform being a first waveform, said waveform display being a first waveform display, said data storage means including means for storing second waveform data representative of a second waveform for producing display signals in order to produce a second waveform display representative thereof on said image display device, said second waveform data being derived from a different source than said first waveform data.

9. The apparatus of claim 1, further including an engine analyzer coupled with said computer and operable to couple with an engine to produce said waveform data representative of the operation of said engine and to provide said waveform data to said computer.

10. The apparatus of claim 1, said waveform data including segment data representative of each segment, said segment data including data points, said segment data presenting an equal number of data points for each corresponding segment.

11. The apparatus of claim 1, said waveform data including segment data representative of each segment, said segment data including data points, said segment data presenting an unequal number of data points for each corresponding segment.

12. A data display apparatus comprising:
an image display device operable to produce a display; and
a computer coupled with said display device including
data storage means for storing waveform data representative of a waveform having a plurality of data segments, and
display signal means responsive to said waveform data for producing display signals representative thereof and for providing said display signals to said monitor for producing a waveform display thereon representative of said waveform,
said computer including cursor means for generating a cursor on said waveform display, said apparatus further including a mouse coupled with said computer and operable to move said cursor and for clicking on a selected one of said segments, said waveform display including position coordinates, said display signal means including means for tracking said cursor and presenting a numerical display of the position coordinates of said cursor.

13. The apparatus of claim 12, said display signal means including means for snapping said cursor along said waveform.

14. The apparatus of claim 12, said display signal means including means for moving vertical cursor line independently.

15. The apparatus of claim 12, said display signal means including means for moving horizontal cursor line independently.

16. The apparatus of claim 12, said display signal means iincluding means for moving crosshair cursor independently of the waveform.

17. The apparatus of claim 12, said waveform display including a plurality of boundary areas adjacent the boundary thereof, said computer including means responsive to positioning of said cursor and said boundary areas for implementing changes in said waveform display corresponding to said boundary areas respectively, said changes including moving the display up, down, left, right, and diagonally.

18. The apparatus of claim 12, further including an engine analyzer coupled with said computer and operable to couple with an engine to produce said waveform data representative of the operation of said engine and to provide said waveform data to said computer.

19. A data display apparatus comprising:
an image display device operable to produce a display; and
a computer coupled with said display device including
data storage means for storing first and second waveform data representative of respective first and second waveforms each having a plurality of data segments, and
display signal means responsive to said waveform data for producing display signals representative thereof and for providing said display signals to said monitor for producing first and second waveform displays thereon representative of said respective waveforms.

20. The apparatus of claim 19, said first and second waveform displays presenting said waveforms one above the other.
